(19) United States
(12) Patent Application Publication
(10) Pub. No.: US 2025/0357067 A1
(43) Pub. Date: Nov. 20, 2025

(54) ABERRATION CORRECTOR FOR SCANNING ELECTRON MICROSCOPE WITH MULTIPLE ELECTRON BEAMS

(71) Applicant: KLA Corporation, Milpitas, CA (US)

(72) Inventors: Alan D. Brodie, Palo Alto, CA (US); Xinrong Jiang, Palo Alto, CA (US)

(21) Appl. No.: 18/668,123

(22) Filed: May 17, 2024

(51) Int. Cl. H01J 37/05; H01J 37/147; H01J 37/153; H01J 37/28

(52) U.S. Cl. CPC H01J 37/05; H01J 37/1472; H01J 37/153; H01J 37/28

(57) ABSTRACT

Two Wien filters are disposed in the path of the charged particle beam between a source and an objective lens, which is downstream of the two Wien filters. The optics also includes a gun lens and a correction lens. The second Wien filter can deflect the secondary electrons to a detector. The charged particle beam may be an electron beam. The charged particle beam may include beamlets.

### FIELD OF THE DISCLOSURE

This disclosure relates to optics for charged particle beam systems.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a workpiece, such as a semiconductor wafer, using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Electron beam imaging systems are used for inspection and metrology of workpieces. Secondary electrons are split from primary electrons to image a workpiece. Chromatic aberration is an obstacle to improve the resolution performance of electron beam imaging systems. The chromatic aberration can be generated by image-forming lens systems because there is a source energy spread in an electron beam emitter. Chromatic aberration also can be found in electron beam splitting systems such as Wien filters or magnetic deflectors. Wien-filter-induced chromatic aberration is sometimes referred to as transfer chromatic (TC) aberration. Improved systems and techniques to address chromatic aberration are needed.

### BRIEF SUMMARY OF THE DISCLOSURE

A system is provided in a first embodiment. The system includes a source that generates a charged particle beam; a stage configured to hold a workpiece in a path of the charged particle beam; an aperture disposed in the path of the charged particle beam between the source and the stage; a gun lens disposed in the path of the charged particle beam between the source and the aperture; an objective lens disposed in the path of the charged particle beam between the aperture and the stage; a first Wien filter disposed in the path of the charged particle beam between the aperture and the objective lens; a second Wien filter disposed in the path of the charged particle beam between the first Wien filter and the objective lens; and a correction lens disposed in the path of the charged particle beam between the aperture and the first Wien filter. Part of the charged particle beam is blocked by an assembly that defines the aperture.

The charged particle beam may be an electron beam and the source may be an electron source. The system can include a detector configured to receive secondary electrons formed when the charged particle beam impacts the workpiece on the stage. The second Wien filter may be configured to deflect the secondary electrons to the detector.

The charged particle beam can be divergent. A strength of the first Wien filter is greater than that of the second Wien filter with reverse polarities.

The charged particle beam can be telecentric. A strength of the first Wien filter is equal to that of the second Wien filter with reverse polarities.

The charged particle beam can be convergent. A strength of the first Wien filter is less than that of the second Wien filter with reverse polarities.

The charged particle beam may include a crossover between the correction lens and the objective lens. A strength of the first Wien filter is equal to that of the second Wien filter with reverse polarities.

The first Wien filter may be configured to correct chromatic aberrations from the first Wien filter and the second Wien filter.

The charged particle beam can include a plurality of beamlets.

A method is provided in a second embodiment. The method includes generating a charged particle beam with a source. The charged particle beam is directed toward a workpiece disposed on a stage. The charged particle beam is directed through a gun lens along a path of the charged particle beam downstream of the source. The charged particle beam is directed through an aperture along the path of the charged particle beam downstream of the gun lens. Part of the charged particle beam is blocked by an assembly that defines the aperture. The charged particle beam is directed through a correction lens along the path of the charged particle beam downstream of the assembly. The charged particle beam is directed through a first Wien filter along the path of the charged particle beam downstream of the correction lens. The charged particle beam is directed through a second Wien filter along the path of the charged particle beam downstream of the first Wien filter. The charged particle beam is directed through an objective lens along the path of the charged particle beam downstream of the second Wien filter. The charged particle beam impacts the workpiece along the path of the charged particle beam downstream of the objective lens.

The charged particle beam may be an electron beam and the source may be an electron source. Secondary electrons can be formed when the charged particle beam impacts the workpiece. The secondary electrons can be detected using a detector. The method can include deflecting the secondary electrons to the detector using the second Wien filter.

The charged particle beam can be divergent. A strength of the first Wien filter is greater than that of the second Wien filter with reverse polarities.

The charged particle beam can be telecentric. A strength of the first Wien filter is equal to that of the second Wien filter with reverse polarities.

The charged particle beam can be convergent. A strength of the first Wien filter is less than that of the second Wien filter with reverse polarities.

The charged particle beam may include a crossover between the correction lens and the objective lens. A strength of the first Wien filter is equal to that of the second Wien filter with reverse polarities.

The first Wien filter may be configured to correct chromatic aberrations from the first Wien filter and the second Wien filter.

The charged particle beam can include a plurality of beamlets.

### DESCRIPTION OF THE DRAWINGS

For a fuller understanding of the nature and objects of the disclosure, reference should be made to the following detailed description taken in conjunction with the accompanying drawings, in which:

FIG. 1 shows a source energy spread of an electron emitter, ΔE;

FIG. 2 shows electron energy dispersion resulted from Wien filter, γ;

FIG. 3 shows transfer chromatic blur at sample dWC due to the Wien filter energy dispersion angle γ;

FIG. 4 shows correcting Wien-induced transfer chromatic aberration in various profiles via an objective lens with a divergent image-forming beam;

FIG. 5 shows correcting Wien-induced transfer chromatic aberration in various profiles via an objective lens with a telecentric image-forming beam;

FIG. 6 shows correcting Wien-induced transfer chromatic aberration in various profiles via an objective lens with a convergent image-forming beam;

FIG. 7 shows correcting Wien-induced transfer chromatic aberration in various profiles via an objective lens with a crossover image-forming beam;

FIG. 8 is an embodiment of a dual-Wien transfer chromatic aberration correction scheme; and

FIG. 9 is an embodiment of a dual-Wien transfer chromatic aberration correction scheme with beamlets.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

A secondary electron (SE) beam is generally split from the primary electron (PE) beam for image-forming a workpiece (e.g., a semiconductor wafer). Embodiments disclosed herein address chromatic aberration that occurs when using a Wien filter.

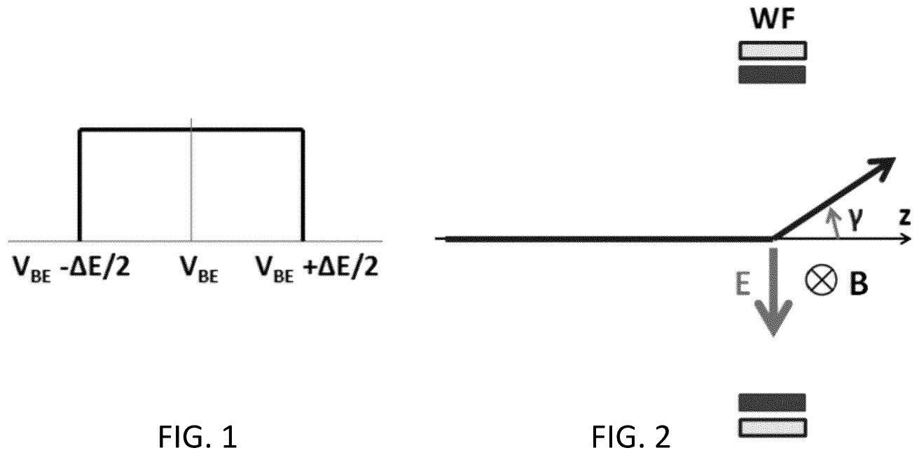

A thermal-field emission (TFE) source can be used as an electron source. The TFE source is characterized by brightness and energy spread. The source energy spread (ΔE), as shown in FIG. 1, is a cause of chromatic aberrations and can degrade resolution. The source energy spread can be 7° or more. The chromatic aberrations may be divided into the lens chromatic aberration, Wien filter chromatic aberrations, and deflection chromatic aberrations. The lens and Wien filter chromatic aberrations may impact the axial resolution. The deflection chromatic aberration may degrade the image uniformity across a field of view (FOV). The Wien filter chromatic aberration and deflection chromatic aberration are sometimes referred to as transfer chromatic aberration.

A Wien filter has perpendicular electric and magnetic fields that can be used as a velocity filter for charged particles like electrons. A Wien filter also can be used to select particles based on their speed. The Wien filter has orthogonal electric and magnetic fields, such that particles with the correct speed will not be affected while other particles will be deflected. Any charged particle in an electric field will feel a force proportional to the charge and field strength. Similarly, any particle moving in a magnetic field will feel a force proportional to the velocity and charge of the particle. In the case of a velocity selector, the magnetic field is at a 90-degree angle to the velocity. Setting the two forces to equal magnitude in opposite directions, any combination of electric and magnetic fields can allow charged particles with only a particular velocity through.

The electron energy dispersion is generated due to different deflections of the electric field and magnetic field in a Wien filter (WF). A Wien filter can balance central energy electrons (i.e., the beam energy (BE) shown in FIG. 1). For the electrons with the energy variation from V_{BE}-ΔE/2 to V_{BE}+ΔE/2, the Wien filter generates an energy dispersion angle, γ, as shown in FIG. 2, given by the following equation.

$$γ ∝ \frac{E}{{V}_{BE}^{2}} * Δ E$$

E is the Wien filter electric field strength, which is balanced by the magnetic flux strength B for the electron with the central beam energy V_{BE}. The magnetic flux density B is given by the following equation.

$$B ∝ E * \sqrt{\frac{m}{{e V}_{BE}}}$$

m is the electron mass and e is the electron charge. The Wien filter energy dispersion angle γ only occurs in the balancing direction, such as the electric field E direction shown in FIG. 2. In the perpendicular direction (i.e., the magnetic flux B direction), the Wien filter energy dispersion angle is zero.

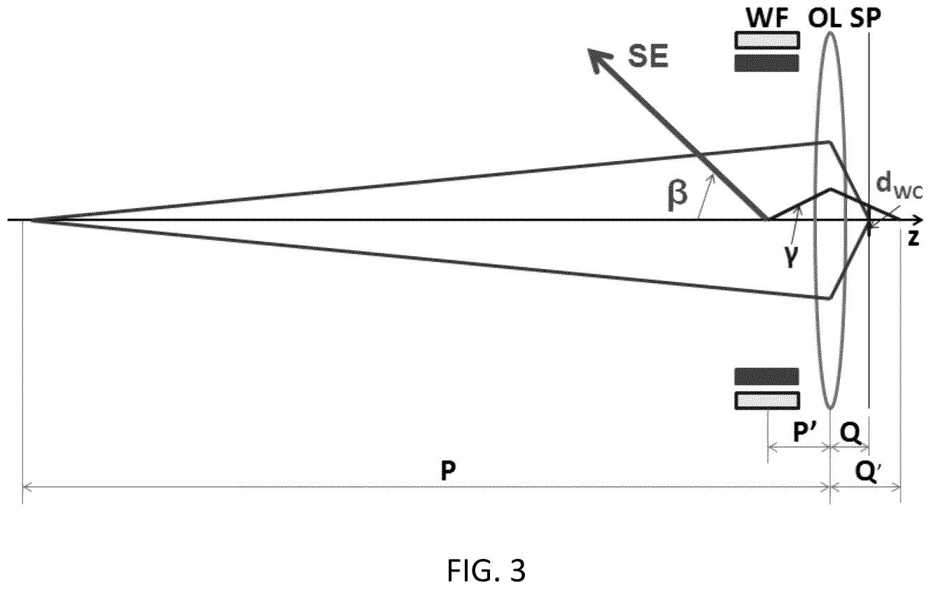

The energy dispersion angle γ at the Wien filter can be equivalent to a chromatic aberration blur at the sample d_{WC}, as shown in FIG. 3. In FIG. 3, assume that the objective lens (OL) imaging relation is given by the object distance P and image distance Q. The Wien filter is placed away from objective lens a distance of P′. The energy-dispersed electron is defocused by the objective lens because the distance P′ is different from the distance P. The defocusing blur (i.e., the d_{WC} in FIG. 3) is, accordingly, the chromatic blur induced by the Wien filter energy dispersion. The Wien transfer chromatic blur can be described as follows.

$${d}_{WC} ∝ \sqrt{\frac{{V}_{BE}}{{V}_{LE}}} * {C}_{c} γ$$

V_{LE} is the electron landing energy voltage at the sample, and C_{C} is chromatic aberration coefficient, which is defined using the following equation that shows C_{C}→0 when P→P′ or C→Q when P→co.

$${C}_{c} = {P}^{′} Q ( \frac{1}{{P}^{′}} - \frac{1}{P} )$$

The primary electron (PE) beam is balanced by the Wien filter while the secondary electron (SE) beam is deflected an angle of β towards the detector. Accordingly, the Wien filter strength (E X B) should be set appropriately. The Wien filter chromatic blur at the sample can be alternatively expressed as follows.

$${d}_{WC} ∝ \frac{Δ E}{{E}_{eff}} * {C}_{c} β$$

This shows that the Wien transfer chromatic aberration is a function of source energy spread (ΔE), Wien filter position (P′), beam energy (V_{BE}), landing energy (V_{LE}), and detector position angle (β). E_{eff} is an effective beam energy provided by the following equation.

$${E}_{eff} = \sqrt{{V}_{BE} {V}_{LE}} ( \frac{{V}_{BE}}{{V}_{BE} - {V}_{LE}} + \sqrt{\frac{{V}_{BE}}{{V}_{BE} - {V}_{LE}}} )$$

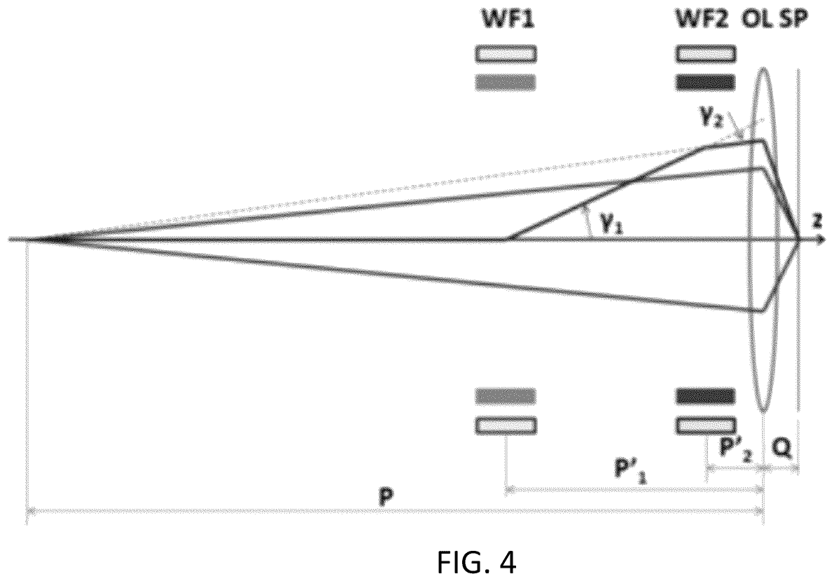

FIGS. 4-7 show Wien transfer chromatic corrections, in which two Wien filters (WF1 and WF2) are arranged along the optical axis. WF2, which is closer to the objective lens, is assumed to deflect the SEs to the side detector with an angle of β. WF1 is deployed to correct the total Wien-filter-induced chromatic aberrations from WF1 and WF2 at the sample. One or both of the Wien filters are global Wein filter with large inner diameters (e.g., >20 mm) and uniform field distributions in central areas. With multiple beams (e.g., hundreds of beams), the size of each beam is much smaller (e.g., <2 mm) than the Wien filter diameter. The directions of the Wien-induced energy dispersion blurs for all beamlets may be the same, such a global Wien filter corrects the chromatic blurs in multiple beams is as effectively as correcting a single beam chromatic blur.

The cancellation condition for the chromatic aberrations is given by the following equations.

$${C}_{c 1} {γ}_{1} + {C}_{c 2} {γ}_{2} = 0$$

$${γ}_{1} = - \frac{{C}_{c 2}}{{C}_{c 1}} {γ}_{2}$$

In these equations, the following two relationships occur.

$${C}_{c 1} = {P}_{1}^{′} Q ( \frac{1}{{P}_{1}^{′}} - \frac{1}{P} )$$

$${C}_{c 2} = {P}_{2}^{′} Q ( \frac{1}{{P}_{2}^{′}} - \frac{1}{P} )$$

The cancellation condition is illustrated in FIGS. 4-7 in which the pre-dispersed electron with the dispersion angle γ₁ in WF1 is moved to compensate the dispersion angle γ₂ in WF2 such that the electron is equivalent to be emitted from the object of the objective lens (OL). The strengths of the WF1 and WF2 (E1/B1 and E2/B2) can be given with the dispersion angles γ₁ and γ₂. The E2/B2 are first given by meeting the SE deflecting angle β, then the γ₂ is defined, and then the γ₁ is determined.

For a typical TFE source with an energy spread around 1 eV, the energy dispersion angle may be from approximately 1 to 5 micro-radians, which would generate severe chromatic blurs on the workpiece if the energy dispersion was not corrected. Hundreds of voltages may be applied on one of Wien filters to deflect the secondary electrons to a detector, and hundreds of voltages may be also applied on another Wien filter to eliminate the energy dispersions induced by the Wien filters.

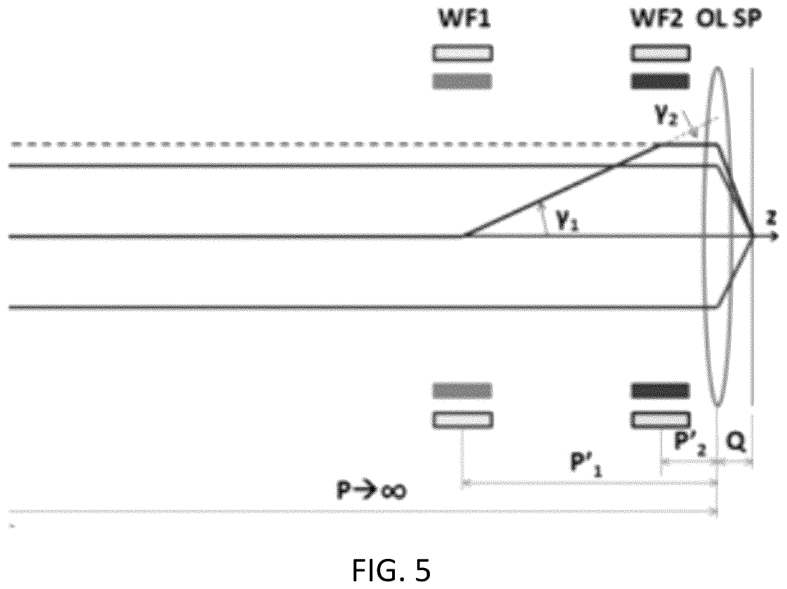

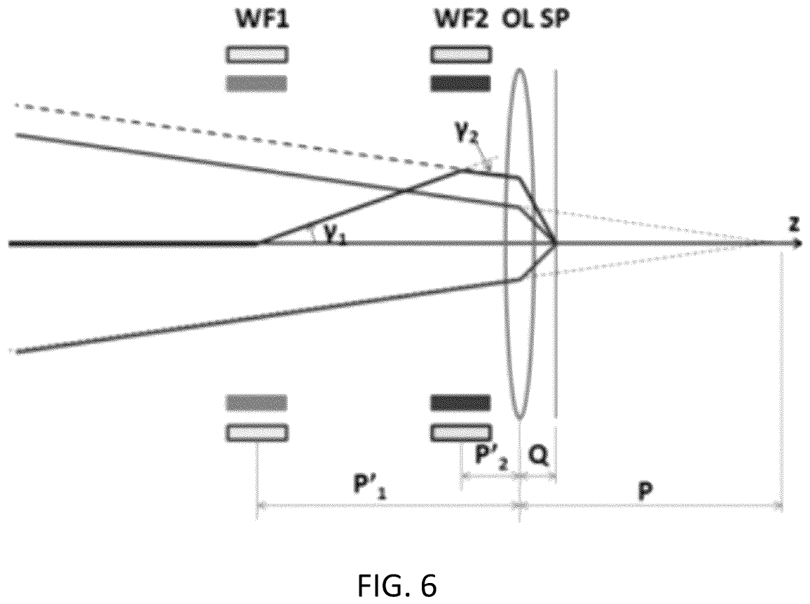

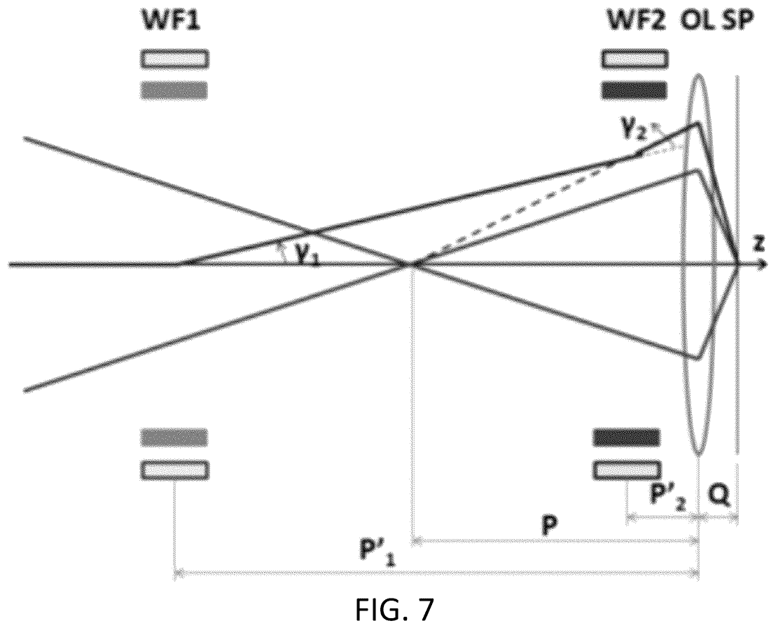

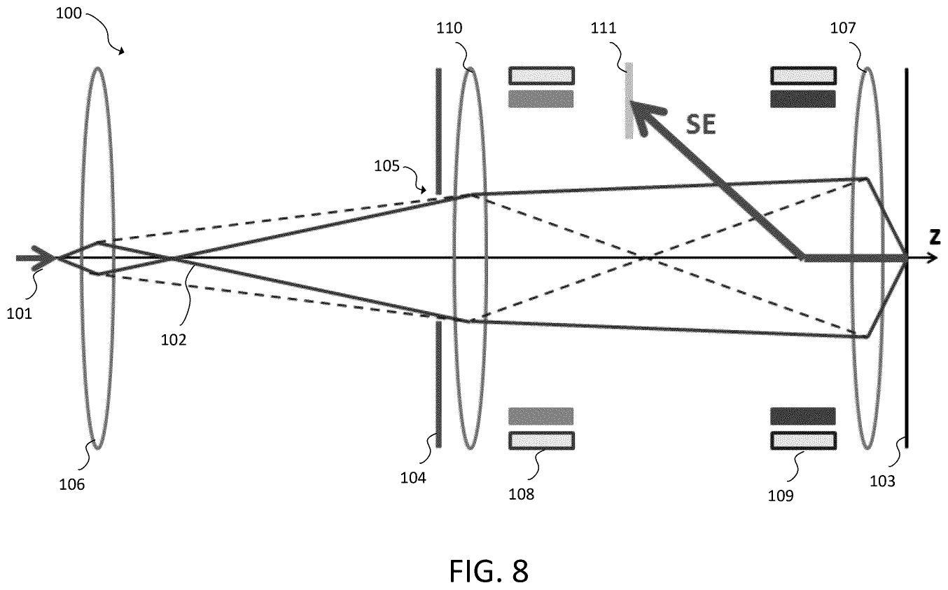

The cancellation condition for the chromatic aberrations using the Wien transfer chromatic correction can be used for any electron or other charged particle beam with a profile of crossover or non-crossover (divergent, telecentric and convergent) between the condenser lens and objective lens in FIG. 8. A divergent beam illuminating the OL is shown in FIG. 4 in which P>P′₁>P′₂ gives C_{C2}>C_{C1}>0, meaning that the WF1 strength should be higher than the WF2 strength with reverse polarities to completely correct the Wien-filter chromatic blurs. A telecentric beam illuminating the objective lens is shown in FIG. 5 in which P→∞ gives C_{C2}=C_{C1}=Q>0, meaning that the WF1 strength should be equal to the WF2 strength with reverse polarities to completely correct the Wien-filter chromatic blurs. A convergent beam illuminating the objective lens is shown in FIG. 6 in which P′₁>P′₂ and P<0 gives C_{C1}>C_{C2}>0, meaning that the WF1 strength should be lower than the WF2 strength with reverse polarities to completely correct the Wien-filter chromatic blurs. A crossover beam illuminating the objective lens is shown in FIG. 7 in which P′₁>P>P′₂ gives C_{C2}>0 and C_{C1}<0, meaning that the WF1 polarity should be the same as the WF2 polarity to completely correct the Wien-filter chromatic blurs. The WF1 strength may be higher (lower) than the WF2 strength, depending on the crossover position with respect to the Wien filter positions.

The Wien transfer chromatic cancellation concept in FIGS. 4-6 can be used in a charged particle metrology system. FIG. 8 shows a dual-Wien transfer chromatic correction scheme with a first Wien filter (WF1) and a second Wien filter (WF2) deployed in between a condenser lens and objective lens along the optical axis z. The second Wien filter is placed proximate to the objective lens for secondary electron deflection and collection. The first Wien filter is placed following the condenser lens and can be used to correct the total chromatic aberrations resulted from the first Wien filter and second Wien filter. The beam profile between the condenser lens and objective lens can be both the crossover and non-crossover (e.g., divergent, telecentric, or convergent).

In an embodiment, the system 100 includes a source 101 that generates a charged particle beam 102. The source 101 can be an electron source with a tip and the charged particle beam 102 can be an electron beam. A stage 103 (SP) is configured to hold a workpiece (e.g., a semiconductor wafer) in a path of the charged particle beam 102.

An assembly 104 with an aperture 105 is positioned in the path of the charged particle beam 102. Part of the charged particle beam 102 is blocked by the assembly 104.

A gun lens 106 is positioned in the path of the charged particle beam 102 between the source 101 and the aperture 105. An objective lens 107 (OL) is positioned in the path of the charged particle beam 102 between the aperture 105 and the stage 103.

A first Wien filter 108 (WF1) is positioned in the path of the charged particle beam 102 between the aperture 105 and the objective lens 107. A second Wien filter 109 (WF2) is positioned in the path of the charged particle beam 102 between the first Wien filter 108 and the objective lens 107.

The first Wien filter 108 and second Wien filter 109 may be designed as octupole deflectors. There are eight electrode plates in an electrostatic deflector. By applying proper voltages on these plates, uniform distribution of electrostatic deflection fields in the central areas may be achieved. These electrodes may be made of magnetic materials. Eight coils may be wound around the magnetic electrodes to constitute a magnetic octupole deflector. Uniform distribution of magnetic deflection fields may be achieved in the central areas if particular currents are applied to the magnetic coils. The first Wien filter 108 and second Wien filter 109 produce rotatable dipole fields. The octopoles can provide good uniformity over the central region (R/8). Higher order pole designs (dodecapole (12), icosapole (20), etc.) may improve the uniformity over the central region.

A correction lens 110 is positioned in the path of the charged particle beam 102 between the aperture 105 and the first Wien filter 108. In an instance, the correction lens 110 may be a condenser lens. A detector 111 receives secondary electrons (SE) formed when the charged particle beam 102 impacts the workpiece on the stage 103. The second Wien filter 109 deflects the secondary electrons to the detector 111. The first Wien filter 108 corrects chromatic aberrations from the first Wien filter 108 and the second Wien filter 109.

In a first example, the charged particle beam 102 is divergent. A strength of the first Wien filter 108 is greater than that of the second Wien filter 109 with reverse polarities.

In a second example, the charged particle beam 102 is telecentric. A strength of the first Wien filter 108 is equal to that of the second Wien filter 109 with reverse polarities.

In a third example, the charged particle beam 102 is convergent. A strength of the first Wien filter 108 is less than that of the second Wien filter 109 with reverse polarities.

In a fourth example, the charged particle beam includes a crossover between the correction lens 110 and the objective lens 107. A strength of the first Wien filter 108 is equal to that of the second Wien filter 109 with reverse polarities.

Typically, hundreds of Volts of Wien filter electrode voltages (and hundreds of milli-Amperes of Wein filter coil currents) may be applied for these instances. The electrode voltages and coil currents may be varied based on the electron beam profiles. The beam currents may be from approximately 0.1 to 100 nA. The beam energies may be from approximately 5 to 50 kV depending on the application. The voltages may be approximately 10% of the beam energy, but this can depend on the diameter and length of the electrodes or poles.

As shown in the diagram of FIG. 8, the charged particle beam 102 is generated using the source 101. The charged particle beam 102 is directed toward a workpiece on the stage 103. The charged particle beam 102 is directed through a gun lens 106 downstream of the source 101, an aperture 105 in an assembly 104 downstream of the gun lens 106, a correction lens 110 downstream of the assembly 104, a first Wien filter 108 downstream of the correction lens 110, a second Wien filter 109 downstream of the first Wien filter 108, and an objective lens 107 downstream of the second Wien filter 109. Part of the charged particle beam 102 is blocked by the assembly 104 that defines the aperture 105. The charged particle beam 102 impacts the workpiece downstream of the objective lens 107. Secondary electrons can be formed when the charged particle beam 102 impacts the workpiece. These secondary electrons can be detected using the detector 111. The secondary electrons can be defected to the detector 111 using the second Wien filter 109.

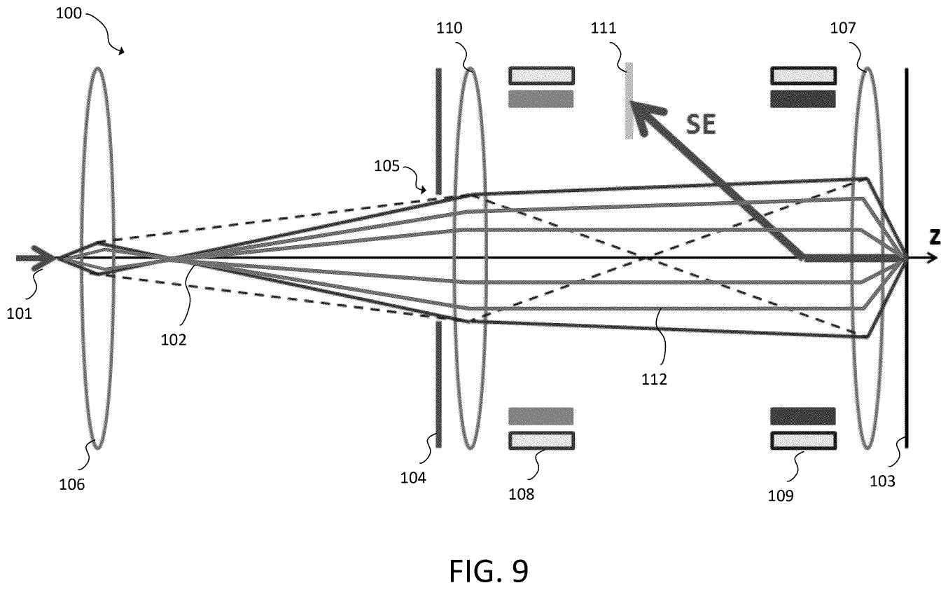

FIG. 9 depicts multiple beamlets 112 within an envelope. A beamlet 112 is a smaller version of the charged particle beam 102. The beamlets 112 may be formed from the charged particle beam 102 (e.g., using an array of apertures). The beamlets 112 also may be individual charged particle beams formed using multiple sources 101. The beamlets 112 are inside an envelope of the charged particle beam 102. Multiple beamlets 112 are imaged on the detector 111. Position information for each beamlet 112 is preserved. Thus, the charged particle beam 102 may be bent off-axis using additional optics. Any optical components in the system can accommodate the beamlets 112 or can include separate apertures or slits for each beamlet.

In another instance, the system of FIG. 8 is duplicated to produce multiple charged particle beams 102.

While disclosed with electron beams, the embodiments disclosed herein can apply to other charged particle beams. Thus, ion beams (e.g., helium ion beams) also can benefit from the embodiments disclosed herein. The source can be an electron beam source, an ion beam source, or other devices.

Other types of workpieces also may be used. For example, the workpiece may be used to manufacture LEDs, solar cells, magnetic discs, flat panels, or polished plates. Defects on other objects also may be classified using techniques and systems disclosed herein.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a source that generates a charged particle beam;
a stage configured to hold a workpiece in a path of the charged particle beam;
an aperture disposed in the path of the charged particle beam between the source and the stage, wherein part of the charged particle beam is blocked by an assembly that defines the aperture;
a gun lens disposed in the path of the charged particle beam between the source and the aperture;
an objective lens disposed in the path of the charged particle beam between the aperture and the stage;
a first Wien filter disposed in the path of the charged particle beam between the aperture and the objective lens;
a second Wien filter disposed in the path of the charged particle beam between the first Wien filter and the objective lens; and
a correction lens disposed in the path of the charged particle beam between the aperture and the first Wien filter.

2. The system of claim 1, wherein the charged particle beam is an electron beam and the source is an electron source.

3. The system of claim 2, further comprising a detector configured to receive secondary electrons formed when the charged particle beam impacts the workpiece on the stage.

4. The system of claim 3, wherein the second Wien filter is configured to deflect the secondary electrons to the detector.

5. The system of claim 1, wherein the charged particle beam is divergent, and wherein a strength of the first Wien filter is greater than that of the second Wien filter with reverse polarities.

6. The system of claim 1, wherein the charged particle beam is telecentric, and wherein a strength of the first Wien filter is equal to that of the second Wien filter with reverse polarities.

7. The system of claim 1, wherein the charged particle beam is convergent, and wherein a strength of the first Wien filter is less than that of the second Wien filter with reverse polarities.

8. The system of claim 1, wherein the charged particle beam includes a crossover between the correction lens and the objective lens, and wherein a strength of the first Wien filter is equal to that of the second Wien filter with reverse polarities.

9. The system of claim 1, wherein the first Wien filter is configured to correct chromatic aberrations from the first Wien filter and the second Wien filter.

10. The system of claim 1, wherein the charged particle beam includes a plurality of beamlets.

11. A method comprising:
generating a charged particle beam with a source;
directing the charged particle beam toward a workpiece disposed on a stage;
directing the charged particle beam through a gun lens along a path of the charged particle beam downstream of the source;
directing the charged particle beam through an aperture along the path of the charged particle beam downstream of the gun lens, wherein part of the charged particle beam is blocked by an assembly that defines the aperture;
directing the charged particle beam through a correction lens along the path of the charged particle beam downstream of the assembly;
directing the charged particle beam through a first Wien filter along the path of the charged particle beam downstream of the correction lens;
directing the charged particle beam through a second Wien filter along the path of the charged particle beam downstream of the first Wien filter;
directing the charged particle beam through an objective lens along the path of the charged particle beam downstream of the second Wien filter; and
impacting the charged particle beam on the workpiece along the path of the charged particle beam downstream of the objective lens.

12. The method of claim 11, wherein the charged particle beam is an electron beam and the source is an electron source.

13. The method of claim 12, further comprising forming secondary electrons when the charged particle beam impacts the workpiece and detecting the secondary electrons using a detector.

14. The method of claim 13, further comprising deflecting the secondary electrons to the detector using the second Wien filter.

15. The method of claim 11, wherein the charged particle beam is divergent, and wherein a strength of the first Wien filter is greater than that of the second Wien filter with reverse polarities.

16. The method of claim 11, wherein the charged particle beam is telecentric, and wherein a strength of the first Wien filter is equal to that of the second Wien filter with reverse polarities.

17. The method of claim 11, wherein the charged particle beam is convergent, and wherein a strength of the first Wien filter is less than that of the second Wien filter with reverse polarities.

18. The method of claim 11, wherein the charged particle beam includes a crossover between the correction lens and the objective lens, and wherein a strength of the first Wien filter is equal to that of the second Wien filter with reverse polarities.

19. The method of claim 11, wherein the first Wien filter is configured to correct chromatic aberrations from the first Wien filter and the second Wien filter.

20. The method of claim 11, wherein the charged particle beam includes a plurality of beamlets.
